(19) United States
(12) Patent Application Publication
(10) Pub. No.: US 2022/0028722 A1
(43) Pub. Date: Jan. 27, 2022

(54) SEMICONDUCTOR DEVICE PRODUCTION METHOD AND LAMINATE FILM FOR TEMPORARY FIXATION MATERIAL

(71) Applicant: Showa Denko Materials Co., Ltd., Chiyoda-ku, Tokyo (JP)

(72) Inventors: Emi MIYAZAWA, Chiyoda-ku, Tokyo (JP); Yoshihito INABA, Chiyoda-ku, Tokyo (JP); Takashi KAWAMORI, Chiyoda-ku, Tokyo (JP); Yasuyuki OOYAMA, Chiyoda-ku, Tokyo (JP); Keisuke NISHIDO, Tokyo (JP)

(21) Appl. No.: 17/296,547

(22) PCT Filed: Nov. 27, 2019
(86) PCT No.: PCT/JP2019/046443

§ 371 Date: May 25, 2021

(30) Foreign Application Priority Data
Nov. 29, 2018 (JP) 2018-223448

(51) Int. Cl. H01L 21/683; H01L 23/00

(52) U.S. Cl. CPC H01L 21/6835; H01L 24/98; H01L 2224/2919; H01L 2224/98; H01L 24/29; H01L 2221/68381

(57) ABSTRACT

A semiconductor device manufacturing method includes a preparation step of preparing a laminated body in which a supporting member, a temporary fixation material layer that generates heat upon absorbing light, and a semiconductor member are laminated in this order, and a separation step of irradiating the temporary fixation material layer in the laminated body with light and thereby separating the semiconductor member from the supporting member. The temporary fixation material layer has a light absorbing layer that generates heat upon absorbing light and a resin cured product layer including a cured product of a curable resin component. The curable resin component includes a hydrocarbon resin, and a storage modulus at 25° C. for the cured product of the curable resin component is 5 to 100 MPa.

### TECHNICAL FIELD

The present invention relates to a semiconductor device manufacturing method and a laminate film for a temporary fixation material.

### BACKGROUND ART

In the field of semiconductor devices, technologies related to a package called SIP (System in Package), in which a plurality of semiconductor elements is laminated, are significantly growing in recent years. In a SIP type package, since a large number of semiconductor elements are laminated, there is a demand for thickness reduction in the semiconductor elements. In response to this demand, in a semiconductor element, an integrated circuit is incorporated into a semiconductor member (for example, a semiconductor wafer), and then, for example, the semiconductor member is subjected to processing treatments such as thickness reduction by grinding the rear surface of the semiconductor member, and individualization by dicing the semiconductor wafer. These semiconductor member processing treatments are usually carried out by temporarily fixing a semiconductor member to a supporting member by means of a temporary fixation material layer (see, for example, Patent Literatures 1 to 3).

The semiconductor member that has been subjected to processing treatments is strongly fixed to the supporting member, with the temporary fixation material layer interposed therebetween. Therefore, in the semiconductor device manufacturing method, it is required that the semiconductor member after the processing treatments can be separated from the supporting member while damage to the semiconductor member and the like are prevented. In Patent Literature 1, as a method for separating such a semiconductor member, a method of physically separating the semiconductor member while heating the temporary fixation material layer is disclosed. Furthermore, in Patent Literatures 2 and 3, methods of separating a semiconductor member by irradiating the temporary fixation material layer with laser light (coherent light) are disclosed.

### CITATION LIST

### Patent Literature

Patent Literature 1: JP No. 2012-126803

Patent Literature 2: JP No. 2016-138182

Patent Literature 3: JP No. 2013-033814

### SUMMARY OF INVENTION

### Technical Problem

However, in the method disclosed in Patent Literature 1, there is a problem that damage caused by thermal history and the like occur in the semiconductor wafer, and the product yield is decreased. On the other hand, the methods disclosed in Patent Literatures 2 and 3 have the following problems: since the irradiation area of laser light is narrow, and the entire semiconductor member should be repeatedly irradiated, it takes much time; since scanning and irradiation are achieved by controlling the focus of laser light, the process becomes complicated; and highly expensive apparatuses are needed.

The present invention was achieved in view of such circumstances, and it is an object of the invention to provide a semiconductor device manufacturing method, by which a temporarily fixed semiconductor member can be easily separated from a supporting member. Furthermore, it is another object of the present invention to provide a laminate film for a temporary fixation material, which is useful as a temporary fixation material.

### Solution to Problem

According to an aspect of the present invention, there is provided a semiconductor device manufacturing method including: a preparation step of preparing a laminated body in which a supporting member, a temporary fixation material layer that generates heat upon absorbing light, and a semiconductor member are laminated in this order; and a separation step of irradiating the temporary fixation material layer in the laminated body with light and thereby separating the semiconductor member from the supporting member, wherein the temporary fixation material layer has a light absorbing layer that generates heat upon absorbing light; and a resin cured product layer including a cured product of a curable resin component, the curable resin component includes a hydrocarbon resin, and a storage modulus at 25° C. for the cured product of the curable resin component is 5 to 100 MPa.

A light source of the light in the separation step may be a xenon lamp. The light in the separation step may be light including at least infrared light.

The separation step may be a step of irradiating the temporary fixation material layer with light through the supporting member.

The curable resin component may further include a thermosetting resin.

According to another aspect of the present invention, there is provided a laminate film for a temporary fixation material for temporarily fixing a semiconductor member to a supporting member, the laminate film having a light absorbing layer that generates heat upon absorbing light and a resin layer including a curable resin component, wherein the curable resin component includes a hydrocarbon resin, and a storage modulus at 25° C. for a cured product of the curable resin component is 5 to 100 MPa.

The thickness of the resin layer may be 50 μm or less.

### Advantageous Effects of Invention

According to the present invention, there is provided a semiconductor device manufacturing method, by which a temporarily fixed semiconductor member can be easily separated from a supporting member. Furthermore, according to the present invention, there is provided a laminate film for a temporary fixation material useful as a temporary fixation material.

### BRIEF DESCRIPTION OF DRAWINGS

FIG. 1 is a schematic cross-sectional view for describing an embodiment of a semiconductor device manufacturing method according to the present invention, and FIGS. 1(a) and 1(b) are schematic cross-sectional views illustrating the respective steps.

FIGS. 2(a), 2(b), and 2(c) are schematic cross-sectional views illustrating an embodiment of a temporary fixation material precursor layer.

FIGS. 3(a), 3(b), 3(c), and 3(d) are schematic cross-sectional views illustrating an embodiment of a laminated body formed using the temporary fixation material precursor layer illustrated in FIG. 2(a).

FIG. 4 is a schematic cross-sectional view for describing an embodiment of the semiconductor device manufacturing method according to the present invention using the laminated body illustrated in FIG. 3(d), and FIGS. 4(a) and 4(b) are schematic cross-sectional views illustrating the respective steps.

FIG. 5 is a schematic cross-sectional view for describing another embodiment of a method for producing the laminated body illustrated in FIG. 1(a), and FIGS. 5(a), 5(b), and 5(c) are schematic cross-sectional views illustrating the respective steps.

### DESCRIPTION OF EMBODIMENTS

Hereinafter, embodiments of the present invention will be described with appropriate reference to the drawings. However, the present invention is not intended to be limited to the following embodiments. In the following embodiments, the constituent elements thereof (also including steps and the like) are not essential unless particularly stated otherwise. The sizes of the constituent elements in the respective diagrams are merely conceptual, and the relative relationship between the sizes of the constituent elements is not limited to that illustrated in the respective drawings.

The same also applies to the numerical values and ranges thereof in the present specification, and the numerical values and the ranges thereof are not intended to limit the present invention. A numerical value range expressed using the term “to” in the present specification represents a range including the numerical values described before and after the term “to” as the minimum value and the maximum value, respectively. With regard to numerical value ranges described stepwise in the present specification, the upper limit or lower limit described in one numerical value range may be substituted with the upper limit or lower limit of another numerical value range described stepwise. Furthermore, with regard to a numerical value range described in the present specification, the upper limit or lower limit of the numerical value range may be substituted with a value shown in the Examples.

In the present specification, (meth)acrylic acid means acrylic acid, or methacrylic acid corresponding thereto. The same also applies to other similar expressions such as (meth)acrylate and (meth)acryloyl group.

[Semiconductor Device Manufacturing Method]

The semiconductor device manufacturing method according to the present embodiment includes: a preparation step of preparing a laminated body in which a supporting member, a temporary fixation material layer that generates heat upon absorbing light (hereinafter, may be simply referred to as “temporary fixation material layer”), and a semiconductor member are laminated in this order; and a separation step of irradiating the temporary fixation material layer in the laminated body with light and thereby separating the semiconductor member from the supporting member.

<Preparation Step for Laminated Body>

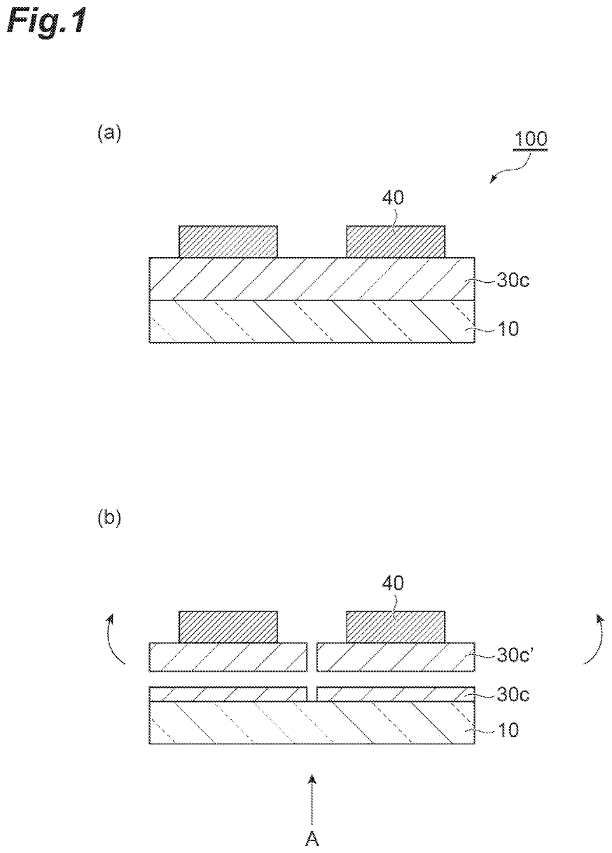

FIG. 1 is a schematic cross-sectional view for describing an embodiment of the semiconductor device manufacturing method of the present invention, and FIGS. 1(a) and 1(b) are schematic cross-sectional views illustrating the respective steps. As illustrated in FIG. 1(a), in the preparation step for a laminated body, a laminated body 100 in which a supporting member 10, a temporary fixation material layer 30c, and a semiconductor member 40 are laminated in this order, is prepared.

The supporting member 10 is not particularly limited; however, for example, the supporting member may be a glass substrate, a resin substrate, a silicon wafer, a metal thin film, or the like. The supporting member 10 may be any substrate that does not obstruct transmission of light, and may be a glass substrate.

The thickness of the supporting member 10 may be, for example, 0.1 to 2.0 mm When the thickness is 0.1 mm or more, handling tends to become easier, and when the thickness is 2.0 mm or less, there is a tendency that the material cost can be suppressed.

The temporary fixation material layer 30c is a layer for temporarily fixing the supporting member 10 and the semiconductor member 40 and is a layer that absorbs light when irradiated with light and then generates heat. The light that is an object of absorption for the temporary fixation material layer 30c may be light including any of infrared light, visible light, or ultraviolet light. Since the light absorbing layer can efficiently generate heat, the light that is the object of absorption for the temporary fixation material layer 30c may be light including at least infrared light. Furthermore, the temporary fixation material layer 30c may be any layer that absorbs infrared light when irradiated with light including infrared light, and then generates heat.

The laminated body 100 illustrated in FIG. 1(a) can be produced by, for example, forming a temporary fixation material precursor layer on a supporting member, disposing a semiconductor member on the temporary fixation material precursor layer, curing a curable resin component in the temporary fixation material precursor layer, and forming a temporary fixation material layer.

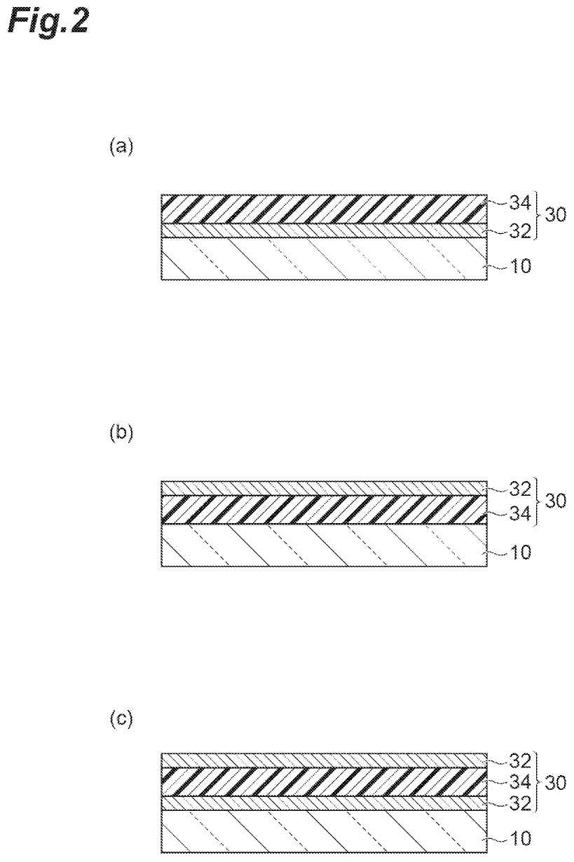

The temporary fixation material precursor layer has a light absorbing layer that generates heat upon absorbing light and a resin layer including a curable resin component. FIGS. 2(a), 2(b), and 2(c) are schematic cross-sectional views illustrating embodiments of the temporary fixation material precursor layer. Regarding the temporary fixation material precursor layer 30, the configuration thereof is not particularly limited so long as the temporary fixation material precursor layer has a light absorbing layer 32 and a resin layer 34; however, examples thereof include a configuration having the light absorbing layer 32 and the resin layer 34 in this order from the supporting member 10 side (FIG. 2(a)); a configuration having the resin layer 34 and the light absorbing layer 32 in this order from the supporting member 10 side (FIG. 2(b)); and a configuration having the light absorbing layer 32, the resin layer 34, and the light absorbing layer 32 in this order (FIG. 2(c)). Among these, the temporary fixation material precursor layer 30 may have a configuration having the light absorbing layer 32 and the resin layer 34 in this order from the supporting member 10 side (FIG. 2(a)). In the following description, an embodiment of using a temporary fixation material precursor layer 30 having the configuration illustrated in FIG. 2(a) will be mainly described in detail.

An embodiment of the light absorbing layer 32 is a layer formed from a conductor that generates heat upon absorbing light (hereinafter, may be simply referred to as “conductor”) (hereinafter, may be referred to as “conductor layer”). The conductor that constitutes such a conductor layer is not particularly limited so long as it is a conductor that generates heat upon absorbing light; however, the conductor is desirably a conductor that generates heat upon absorbing infrared light. Examples of the conductor include metals such as chromium, copper, titanium, silver, platinum, and gold; alloys such as nickel-chromium, stainless steel, and copper-zinc; metal oxides such as indium tin oxide (ITO), zinc oxide, and niobium oxide; and carbon materials such as conductive carbon. These may be used singly or in combination of two or more kinds thereof. Among these, the conductor may be chromium, titanium, copper, aluminum, silver, gold, platinum, or carbon.

The light absorbing layer 32 may be composed of a plurality of conductor layers. Such a light absorbing layer may be, for example, a light absorbing layer composed of a first conductor layer provided on a supporting member 10; and a second conductor layer provided on a surface of the first conductor layer, the surface being on the opposite side of the supporting member 10. The conductor in the first conductor layer may be titanium from the viewpoints of adhesiveness to a supporting member (for example, glass), film-forming properties, heat conductivity, heat capacity, and the like. The conductor in the second conductor layer may be copper, aluminum, silver, gold, or platinum from the viewpoints of high coefficient of expansion, high thermal conduction, and the like, and among these, the conductor is preferably copper or aluminum.

The conductor layers as the light absorbing layer 32 can be directly formed on the supporting member 10 by subjecting these conductors to physical vapor deposition (PVD) such as vacuum vapor deposition or sputtering, or to chemical vapor deposition (CVD) such as electroplating, electroless plating, or plasma chemical vapor deposition. Among these, the conductor layer may be formed using physical vapor deposition, or may be formed using sputtering or vacuum vapor deposition, from the viewpoint that the conductor layer can be formed in a large area.

The thickness of an embodiment of the light absorbing layer 32 may be 1 to 5000 nm (0.001 to 5 μm) or 50 to 3000 nm (0.05 to 3 μm), from the viewpoint of light detachability. In a case in which the light absorbing layer 32 is composed of a first conductor layer and a second conductor layer, the thickness of the first conductor layer may be 1 to 1000 nm, 5 to 500 nm, or 10 to 100 nm, and the thickness of the second conductor layer may be 1 to 5000 nm, 10 to 500 nm, 30 to 300 nm, or 50 to 200 nm.

Another embodiment of the light absorbing layer 32 is a layer which contains a cured product of a curable resin composition including electroconductive particles that generate heat upon absorbing light. The curable resin composition may contain electroconductive particles and a curable resin component.

The electroconductive particles are not particularly limited so long as they generate heat upon absorbing light; however, the electroconductive particles may be any particles that generate heat upon absorbing infrared light. The electroconductive particles may be, for example, at least one selected from the group consisting of silver powder, copper powder, nickel powder, aluminum powder, chromium powder, iron powder, brass powder, tin powder, a titanium alloy, gold powder, a copper alloy powder, copper oxide powder, silver oxide powder, tin oxide powder, and electroconductive carbon powder. From the viewpoints of handleability and safety, the electroconductive particles may also be at least one selected from the group consisting of silver powder, copper powder, silver oxide powder, copper oxide powder, and carbon powder. Furthermore, the electroconductive particles may be particles having a core formed from a resin or a metal and having this core plated with a metal such as nickel, gold, or silver. Moreover, the electroconductive particles may be particles having the surface treated with a surface treatment agent, from the viewpoint of dispersibility in a solvent.

The content of the electroconductive particles may be 10 to 90 parts by mass with respect to 100 parts by mass of the total amount of the components other than the electroconductive particles of the curable resin composition. Meanwhile, the organic solvent that will be described below is not included in the components other than the electroconductive particles of the curable resin composition. The content of the electroconductive particles may be 15 parts by mass or more, 20 parts by mass or more, or 25 parts by mass or more. The content of the electroconductive particles may be 80 parts by mass or less or 50 parts by mass or less.

The curable resin component may be a curable resin component that is cured by heat or light. The curable resin component may include, for example, a thermosetting resin, a curing agent, and a curing accelerator. Regarding the thermosetting resin, curing agent, and curing accelerator, for example, those listed as examples for the curable resin component in the resin layer that will be described below, and the like can be used. The total content of the thermosetting resin and the curing agent may be 10 to 90 parts by mass with respect to 100 parts by mass of the total amount of the components other than the electroconductive particles of the curable resin composition. The content of the curing accelerator may be 0.01 to 5 parts by mass with respect to 100 parts by mass of the total amount of the thermosetting resin and the curing agent.

The light absorbing layer 32 can be formed from a curable resin composition including electroconductive particles that generate heat upon absorbing light. The curable resin composition may be used as a varnish of the curable resin composition diluted with an organic solvent. Examples of the organic solvent include acetone, ethyl acetate, butyl acetate, and methyl ethyl ketone (MEK). These organic solvents may be used singly or in combination of two or more kinds thereof. The solid component concentration in the varnish may be 10% to 80% by mass based on the total mass of the varnish.

The light absorbing layer 32 can be formed by directly applying the curable resin composition on the supporting member 10. In the case of using a varnish of the curable resin composition diluted in an organic solvent, the light absorbing layer can be formed by applying the curable resin composition on the supporting member 10 and removing the solvent by heating and drying the composition.

The thickness of another embodiment of the light absorbing layer 32 may be 1 to 5000 nm (0.001 to 5 μm) or 50 to 3000 nm (0.05 to 3 μm) from the viewpoint of light detachability.

Subsequently, the resin layer 34 is formed on the light absorbing layer 32.

The resin layer 34 is a layer that does not contain electroconductive particles and is a layer including a curable resin component that is cured by heat or light. The resin layer 34 may be a layer formed from a curable resin component. The curable resin component includes a hydrocarbon resin, and the storage modulus at 25° C. for a cured product of the curable resin component is 5 to 100 MPa. In the following description, the case in which the resin layer 34 is a layer formed from a curable resin component will be described in detail.

The hydrocarbon resin is a resin in which the main skeleton is composed of a hydrocarbon. Examples of such a hydrocarbon resin include an ethylene-propylene copolymer, an ethylene-1-butene copolymer, an ethylene-propylene-1-butene copolymer elastomer, an ethylene-1-hexene copolymer, an ethylene-1-octene copolymer, an ethylene-styrene copolymer, an ethylene-norbornene copolymer, a propylene-1-butene copolymer, an ethylene-propylene-non-conjugated diene copolymer, an ethylene-1-butene-non-conjugated diene copolymer, an ethylene-propylene-1-butene-non-conjugated diene copolymer, polyisoprene, polybutadiene, a styrene-butadiene-styrene block copolymer (SBS), a styrene-isoprene-styrene block copolymer (SIS), a styrene-ethylene-butylene-styrene block copolymer (SEBS), and a styrene-ethylene-propylene-styrene block copolymer (SEPS). These hydrocarbon resins may have been subjected to a hydrogenation treatment. Furthermore, these hydrocarbon resins may be carboxy-modified by means of maleic anhydride or the like. Among these, the hydrocarbon resin may include a hydrocarbon resin including a monomer unit derived from styrene (styrene-based resin) or may include a styrene-ethylene-butylene-styrene block copolymer (SEBS).

The Tg of the hydrocarbon resin may be −100° C. to 500° C., −50° C. to 300° C., or −50° C. to 50° C. In a case in which the Tg of the hydrocarbon resin is 500° C. or lower, there is a tendency that flexibility is easily secured when a film-shaped temporary fixation material is formed, and low-temperature stickability can be enhanced. In a case in which the Tg of the hydrocarbon resin is −100° C. or higher, there is a tendency that deterioration of handleability and detachability caused by flexibility increasing excessively when a film-shaped temporary fixing material is formed, can be suppressed.

The Tg of the hydrocarbon resin is a mid-point glass transition temperature value obtainable by differential scanning calorimetry (DSC). The Tg of the hydrocarbon resin is specifically a mid-point glass transition temperature calculated following a method in accordance with JIS K 7121 by measuring the calorific change under the conditions of a rate of temperature increase of 10° C./min and a measurement temperature of −80° C. to 80° C.

The weight average molecular weight (Mw) of the hydrocarbon resin may be 10000 to 5000000 or 100000 to 2000000. When the weight average molecular weight is 10000 or more, the heat resistance of the temporary fixation material layer to be formed tends to be easily secured. In a case in which the weight average molecular weight is 5000000 or less, there is a tendency that deterioration of flow and deterioration of stickability are easily suppressed when a film-like temporary fixation material layer is formed. Meanwhile, the weight average molecular weight is a value converted relatively to polystyrene standards, which is obtainable using a calibration curve based on polystyrene standards and measured by gel permeation chromatography (GPC).

The content of the hydrocarbon resin can be appropriately set such that the storage modulus at 25° C. for a cured product of the curable resin component is in the range of 5 to 100 MPa. The content of the hydrocarbon resin may be, for example, 40 to 90 parts by mass with respect to 100 parts by mass of the total amount of the curable resin component. The content of the hydrocarbon resin may be 50 parts by mass or more or 60 parts by mass or more. The content of the hydrocarbon resin may be 85 parts by mass or less or 80 parts by mass or less. When the content of the hydrocarbon resin is in the above-described range, the thin film-forming properties and flatness of the temporary fixation material layer tend to be superior.

The curable resin component may include a thermosetting resin in addition to the hydrocarbon resin. Here, the thermosetting resin means a resin that is cured by heat and is a concept that does not include the above-described hydrocarbon resin. Examples of the thermosetting resin include an epoxy resin, an acrylic resin, a silicone resin, a phenolic resin, a thermosetting polyimide resin, a polyurethane resin, a melamine resin, and a urea resin. These may be used singly or in combination of two or more kinds thereof. Among these, the thermosetting resin may be an epoxy resin from the viewpoint of being superior in terms of heat resistance, workability, and reliability. In the case of using an epoxy resin as the thermosetting resin, the epoxy resin may be used in combination with an epoxy resin curing agent.

The epoxy resin is not particularly limited so long as it is cured and then acquires heat-resistant action. Examples of the epoxy resin include bifunctional epoxy resins such as a bisphenol A type epoxy; and novolac type epoxy resins such as a phenol novolac type epoxy resin and a cresol novolac type epoxy resin. Furthermore, the epoxy resin may be a polyfunctional epoxy resin, a glycidylamine type epoxy resin, a heterocyclic ring-containing epoxy resin, or an alicyclic epoxy resin.

In the case of using an epoxy resin as the thermosetting resin, the curable resin component may include an epoxy resin curing agent. Regarding the epoxy resin curing agent, any known curing agent that is conventionally used can be used. Examples of the epoxy resin curing agent include an amine, a polyamide, an acid anhydride, a polysulfide, and boron trifluoride; bisphenols having two or more phenolic hydroxyl groups in one molecule, such as bisphenol A, bisphenol F, and bisphenol S; and phenolic resins such as a phenol novolac resin, a bisphenol A novolac resin, a cresol novolac resin, and a phenol aralkyl resin.

The total content of the thermosetting resin and the curing agent may be 10 to 60 parts by mass with respect to 100 parts by mass of the total amount of the curable resin component. The total content of the thermosetting resin and the curing agent may be 15 parts by mass or more or 20 parts by mass or more. The total content of the thermosetting resin and the curing agent may be 50 parts by mass or less or 40 parts by mass or less. When the total content of the thermosetting resin and the curing agent is in the above-described range, the thin film-forming properties and flatness of the temporary fixation material layer tend to be superior. When the total content of the thermosetting resin and the curing agent is in the above-described range, heat resistance tends to be superior.

The curable resin component may further include a curing accelerator. Examples of the curing accelerator include an imidazole derivative, a dicyandiamide derivative, a dicarboxylic acid dihydrazide, triphenylphosphine, tetraphenylphosphonium tetraphenylborate, 2-ethyl-4-methylimidazole tetraphenylborate, and 1,8-diazabicyclo[5,4,0]undecene-7-tetraphenylborate. These may be used singly or in combination of two or more kinds thereof.

The content of the curing accelerator may be 0.01 to 5 parts by mass with respect to 100 parts by mass of the total amount of the thermosetting resin and the curing agent. When the content of the curing accelerator is in the above-described range, curability is enhanced, and heat resistance tends to be superior.

The curable resin component may further include a polymerizable monomer and a polymerization initiator. The polymerizable monomer is not particularly limited so long as it is polymerized by heating or irradiation with ultraviolet radiation or the like. From the viewpoint of the selectivity and easy availability of the material, the polymerizable monomer may be, for example, a compound having a polymerizable functional group such as an ethylenically unsaturated group. Examples of the polymerizable monomer include a (meth)acrylate, a halogenated vinylidene, a vinyl ether, a vinyl ester, vinylpyridine, vinylamide, and an arylated vinyl. Among these, the polymerizable monomer may be a (meth)acrylate. The (meth)acrylate may be any of a monofunctional (unifunctional), bifunctional, or trifunctional or higher functional (meth)acrylate; however, from the viewpoint of obtaining sufficient curability, the (meth)acrylate may be a bifunctional or higher-functional (meth)acrylate.

Examples of a monofunctional (meth)acrylate include (meth)acrylic acid; aliphatic (meth)acrylates such as methyl (meth)acrylate, ethyl (meth)acrylate, butyl (meth)acrylate, isobutyl (meth)acrylate, tert-butyl (meth)acrylate, butoxyethyl (meth)acrylate, isoamyl (meth)acrylate, hexyl (meth)acrylate, 2-ethylhexyl (meth)acrylate, heptyl (meth)acrylate, octylheptyl (meth)acrylate, nonyl (meth)acrylate, decyl (meth)acrylate, 2-hydroxyethyl (meth)acrylate, 2-hydroxypropyl (meth)acrylate, 3-chloro-2-hydroxypropyl (meth)acrylate, 2-hydroxybutyl (meth)acrylate, methoxy polyethylene glycol (meth)acrylate, ethoxy polyethylene glycol (meth)acrylate, methoxy polypropylene glycol (meth)acrylate, ethoxy polypropylene glycol (meth)acrylate, and mono(2-(meth)acryloyloxyethyl) succinate; and aromatic (meth)acrylates such as benzyl (meth)acrylate, phenyl (meth)acrylate, o-biphenyl (meth)acrylate, 1-naphthyl (meth)acrylate, 2-naphthyl (meth)acrylate, phenoxyethyl (meth)acrylate, p-cumylphenoxyethyl (meth)acrylate, o-phenylphenoxyethyl (meth)acrylate, 1-naphthoxyethyl (meth)acrylate, 2-naphthoxyethyl (meth)acrylate, phenoxy polyethylene glycol (meth)acrylate, nonylphenoxy polyethylene glycol (meth)acrylate, phenoxy polypropylene glycol (meth)acrylate, 2-hydroxy-3-phenoxypropyl (meth)acrylate, 2-hydroxy-3-(o-phenylphenoxy)propyl (meth)acrylate, 2-hydroxy-3-(1-naphthoxy)propyl (meth)acrylate, and 2-hydroxy-3-(2-naphthoxy)propyl (meth)acrylate.

Examples of a bifunctional (meth)acrylate include aliphatic (meth)acrylates such as ethylene glycol di(meth)acrylate, diethylene glycol di(meth)acrylate, triethylene glycol di(meth)acrylate, tetraethylene glycol di(meth)acrylate, polyethylene glycol di(meth)acrylate, propylene glycol di(meth)acrylate, dipropylene glycol di(meth)acrylate, tripropylene glycol di(meth)acrylate, tetrapropylene glycol di(meth)acrylate, polypropylene glycol di(meth)acrylate, ethoxylated polypropylene glycol di(meth)acrylate, 1,3-butanediol di(meth)acrylate, 1,4-butanediol di(meth)acrylate, neopentyl glycol di(meth)acrylate, 3-methyl-1,5-pentanediol di(meth)acrylate, 1,6-hexanediol di(meth)acrylate, 2-butyl-2-ethyl-1,3-propanediol di(meth)acrylate, 1,9-nonanediol di(meth)acrylate, 1,10-decanediol di(meth)acrylate, glycerin di(meth)acrylate, tricyclodecane dimethanol (meth)acrylate, and ethoxylated 2-methyl-1,3-propanediol di(meth)acrylate; and aromatic (meth)acrylates such as ethoxylated bisphenol A di(meth)acrylate, propoxylated bisphenol A di(meth)acrylate, ethoxylated propoxylated bisphenol A di(meth)acrylate, ethoxylated bisphenol F di(meth)acrylate, propoxylated bisphenol F di(meth)acrylate, ethoxylated propoxylated bisphenol F di(meth)acrylate, ethoxylated fluorene type di(meth)acrylate, propoxylated fluorene type di(meth)acrylate, and ethoxylated propoxylated fluorene type di(meth)acrylate.

Examples of a polyfunctional (meth)acrylate of trifunctionality or higher functionality include aliphatic (meth)acrylates such as trimethylolpropane tri(meth)acrylate, ethoxylated trimethylolpropane tri(meth)acrylate, propoxylated trimethylolpropane tri(meth)acrylate, ethoxylated propoxylated trimethylolpropane tri(meth)acrylate, pentaerythritol tri(meth)acrylate, ethoxylated pentaerythritol tri(meth)acrylate, propoxylated pentaerythritol tri(meth)acrylate, ethoxylated propoxylated pentaerythritol tri(meth)acrylate, pentaerythritol tetra(meth)acrylate, ethoxylated pentaerythritol tetra(meth)acrylate, propoxylated pentaerythritol tetra(meth)acrylate, ethoxylated propoxylated pentaerythritol tetra(meth)acrylate, ditrimethylolpropane tetraacrylate, and dipentaerythritol hexa(meth)acrylate; and aromatic epoxy (meth)acrylates such as phenol novolac type epoxy (meth)acrylate and cresol novolac type epoxy (meth)acrylate.

These (meth)acrylates may be used singly or in combination of two or more kinds thereof. Furthermore, these (meth)acrylates may also be used in combination with other polymerizable monomers.

The content of the polymerizable monomer may be 10 to 60 parts by mass with respect to 100 parts by mass of the total amount of the curable resin component.

The polymerization initiator is not particularly limited so long as it is an agent that initiates polymerization by heating or irradiation with ultraviolet radiation or the like. For example, in a case in which a compound having an ethylenically unsaturated group is used as a polymerizable monomer, the polymerizable initiator may be a thermal radical polymerization initiator or a photoradical polymerization initiator.

Examples of the thermal radical polymerization initiator include diacyl peroxides such as octanoyl peroxide, lauroyl peroxide, stearyl peroxide, and benzoyl peroxide; peroxy esters such as t-butyl peroxypivalate, t-hexyl peroxypivalate, 1,1,3,3-tetramethylbutyl peroxy-2-ethylhexanoate, 2,5-dimethyl-2,5-bis(2-ethylhexanoylperoxy)hexane, t-hexyl peroxy-2-ethylhexanoate, t-butyl peroxy-2-ethylhexanoate, t-butyl peroxyisobutyrate, t-hexyl peroxyisopropyl monocarbonate, t-butyl peroxy-3,5,5-trimethylhexanoate, t-butyl peroxylaurylate, t-butyl peroxyisopropyl monocarbonate, t-butyl peroxy-2-ethylhexyl monocarbonate, t-butyl peroxybenzoate, t-hexyl peroxybenzoate, 2,5-dimethyl-2,5-bis(benzoylperoxy)hexane, and t-butyl peroxyacetate; and azo compounds such as 2,2′-azobisisobutyronitrile, 2,2′-azobis(2,4-dimethylvaleronitrile), and 2,2′-azobis(4-methoxy-2′-dimethylvaleronitrile).

Examples of the photoradical polymerization initiator include benzoin ketals such as 2,2-dimethoxy-1,2-diphenylethan-1-one; α-hydroxy ketones such as 1-hydroxycyclohexyl phenyl ketone, 2-hydroxy-2-methyl-1-phenylpropan-1-one, and 1-[4-(2-hydroxyethoxy)phenyl]-2-hydroxy-2-methyl-1-propan-1-one; phosphine oxides such as bis(2,4,6-trimethylbenzoyl)phenyl phosphine oxide, bis(2,6-dimethoxybenzoyl)-2,4,4-trimethylpentyl phosphine oxide, and 2,4,6-trimethylbenzoyl diphenyl phosphine oxide.

These thermal and photoradical polymerization initiators may be used singly or in combination of two or more kinds thereof.

The content of the polymerization initiator may be 0.01 to 5 parts by mass with respect to 100 parts by mass of the total amount of the polymerizable monomer.

The curable resin component may further include an insulative filler, a sensitizer, an oxidation inhibitor, and the like as other components.

An insulative filler can be added for the purpose of imparting low thermal expandability and low hygroscopic properties to a resin layer. Examples of the insulative filler include non-metal inorganic fillers such as silica, alumina, boron nitride, titania, glass, and ceramic. These insulative fillers may be used singly or in combination of two or more kinds thereof. From the viewpoint of dispersibility in a solvent, the insulative filler may be particles having the surface treated with a surface treatment agent. Regarding the surface treatment agent, agents similar to the above-mentioned silane coupling agents can be used.

The content of the insulative filler may be 5 to 20 parts by mass with respect to 100 parts by mass of the total amount of the curable resin component. When the content of the insulative filler is in the above-described range, heat resistance tends to be further enhanced without obstructing light transmission. Furthermore, when the content of the insulative filler is in the above-described range, there is also a possibility of contributing to light detachability.

Examples of the sensitizer include anthracene, phenanthrene, chrysene, benzopyrene, fluoranthene, rubrene, pyrene, xanthone, indanthrene, thioxanthen-9-one, 2-isopropyl-9H-thioxanthen-9-one, 4-isopropyl-9H-thioxanthen-9-one, and 1-chloro-4-propoxythioxanthone.

The content of the sensitizer may be 0.01 to 10 parts by mass with respect to 100 parts by mass of the total amount of the curable resin component. When the content of the sensitizer is in the above-described range, the influence of the curable resin component on characteristics and thin film properties tends to be small.

Examples of the oxidation inhibitor include quinone derivatives such as benzoquinone and hydroquinone; phenol derivatives such as 4-methoxyphenol and 4-t-butylcatechol; aminoxyl derivatives such as 2,2,6,6-tetramethylpiperidin-1-oxyl and 4-hydroxy-2,2,6,6-tetramethylpiperidin-1-oxyl; and hindered amine derivatives such as tetramethylpiperidyl methacrylate.

The content of the oxidation inhibitor may be 0.1 to 10 parts by mass with respect to 100 parts by mass of the total amount of the curable resin component. When the content of the oxidation inhibitor is in the above-described range, decomposition of the curable resin component is suppressed, and there is a tendency that contamination can be prevented.

The storage modulus at 25° C. for a cured product of the curable resin component (resin cured product layer that will be described below) is 5 to 100 MPa. The storage modulus at 25° C. for the cured product of the curable resin component may be 5.5 MPa or higher, 6 MPa or higher, or 6.3 MPa or higher and may be 90 MPa or lower, 80 MPa or lower, 70 MPa or lower, or 65 MPa or lower. The storage modulus at 25° C. for the cured product of the curable resin component can be appropriately adjusted, and the storage modulus at 25° C. for the cured product of the curable resin component can be enhanced by, for example, increasing the proportion of the hydrocarbon resin, applying a hydrocarbon resin having a high Tg, or adding an insulative filler. When the storage modulus at 25° C. for the cured product of the curable resin component is 5 MPa or higher, handleability is enhanced, a chip and the like can be easily temporarily fixed to the supporting member without bending, cohesive failure is not likely to occur at the time of detaching, and the residue tends to decrease. When the storage modulus at 25° C. for the cured product of the curable resin component is 100 MPa or lower, there is a tendency that positional shifting can be made small when a chip and the like are mounted on the supporting member. Meanwhile, according to the present specification, the storage modulus for a cured product of the curable resin component means a storage modulus that is measured by the curing method and measurement procedure described in the Examples.

The storage modulus at 250° C. for a cured product of the curable resin component is not particularly limited; however, for example, the storage modulus may be 0.70 to 2.00 MPa. The storage modulus at 250° C. for a cured product of the curable resin component may be 0.80 MPa or higher, 0.85 MPa or higher, or 0.90 MPa or higher and may be 1.90 MPa or lower, 1.80 MPa or lower, or 1.75 MPa or lower.

The resin layer 34 can be formed from a curable resin component including a hydrocarbon resin (curable resin composition that does not include electroconductive particles). The curable resin component may be used as a varnish of the curable resin component diluted in a solvent. The solvent is not particularly limited so long as it can dissolve components other than an insulative filler. Examples of the solvent include aromatic hydrocarbons such as toluene, xylene, mesitylene, cumene, and p-cymene; aliphatic hydrocarbons such as hexane and heptane; cyclic alkanes such as methylcyclohexane; cyclic ethers such as tetrahydrofuran and 1,4-dioxane; ketones such as acetone, methyl ethyl ketone, methyl isobutyl ketone, cyclohexanone, and 4-hydroxy-4-methyl-2-pentanone; esters such as methyl acetate, ethyl acetate, butyl acetate, methyl lactate, ethyl lactate, and γ-butyrolactone; carbonic acid esters such as ethylene carbonate and propylene carbonate; and amides such as N,N-dimethylformamide, N,N-dimethylacetamide, and N-methyl-2-pyrrolidone. These solvents may be used singly or in combination of two or more kinds thereof. Among these, from the viewpoints of solubility and the boiling point, the solvent may be toluene, xylene, heptane, or cyclohexane. The solid component concentration in the varnish may be 10% to 80% by mass based on the total mass of the varnish.

A varnish of the curable resin component can be prepared by mixing and kneading a curable resin component including a hydrocarbon resin and a solvent. Mixing and kneading can be carried out by appropriately combining conventional dispersing machines such as a stirrer, a Raikai mixer, a three-roll mill, and a bead mill.

The resin layer 34 can be formed by directly applying the curable resin component on the light absorbing layer 32. In the case of using a varnish of the curable resin component diluted in a solvent, The resin layer can be formed by applying the varnish of the curable resin component on the light absorbing layer 32 and removing the solvent by heating and drying the varnish. Furthermore, the resin layer 34 can be formed by producing a curable resin component film formed from the curable resin component.

The thickness of the resin layer 34 can be adjusted according to the thickness of the temporary fixation material layer 20. The thickness of the resin layer 34 may be, for example, 50 μm or less from the viewpoint of stress relaxation. The thickness of the resin layer 34 may be 0.1 to 40 μm or 1 to 30 μm.

The temporary fixation material precursor layer 30 can be produced by producing a laminate film having the light absorbing layer 32 and the resin layer 34 (hereinafter, may be referred to as “laminate film for a temporary fixation material”) in advance and laminating this such that the light absorbing layer 32 and the supporting member 10 come into contact with each other.

The configuration of the light absorbing layer 32 and the resin layer 34 in the laminate film for a temporary fixation material is not particularly limited as long as it has the light absorbing layer 32 and the resin layer 34; however, examples thereof include a configuration having the light absorbing layer 32 and the resin layer 34, and a configuration having the light absorbing layer 32, the resin layer 34, and the light absorbing layer 32 in this order. Among these, the laminate film for a temporary fixation material may have a configuration having the light absorbing layer 32 and the resin layer 34. The light absorbing layer 32 may be a layer formed from a conductor (conductor layer) or may be a layer containing electroconductive particles. The laminate film for a temporary fixation material may be provided on a supporting film, and if necessary, a protective film may be provided on the surface on the opposite side of the supporting film.

The supporting film is not particularly limited, and examples thereof include films of polyesters such as polyethylene terephthalate (PET), polybutylene terephthalate, and polyethylene naphthalate; polyolefins such as polyethylene and polypropylene; polycarbonate, polyamide, polyimide, polyamideimide, polyetherimide, polyether sulfide, polyether sulfone, polyether ketone, polyphenylene ether, polyphenylene sulfide, poly(meth)acrylate, polysulfone, and liquid crystal polymers. These may be subjected to a release treatment. The thickness of the supporting film may be, for example, 3 to 250 μm.

Examples of the protective film include polyesters such as polyethylene terephthalate, polybutylene terephthalate, and polyethylene naphthalate; and polyolefins such as polyethylene and polypropylene. The thickness of the protective film may be, for example, 10 to 250 μm.

The thickness of the light absorbing layer 32 in the laminate film for a temporary fixation material may be 1 to 5000 nm (0.001 to 5 μm) or 50 to 3000 nm (0.05 to 3 μm), from the viewpoint of easy detachability.

The thickness of the resin layer 34 in the laminate film for a temporary fixation material may be, for example, 50 μm or less from the viewpoint of stress relaxation. The thickness of the resin layer 34 may be 0.1 to 40 μm or 1 to 30 μm.

The thickness of the laminate film for a temporary fixation material can be adjusted according to the desired thickness of the temporary fixation material layer. The thickness of the laminate film for a temporary fixation material may be 0.1 to 55 μm or 10 to 40 μm from the viewpoint of stress relaxation.

The temporary fixation material precursor layer 30 having the configuration illustrated in FIG. 2(b) can be produced by, for example, forming the resin layer 34 on the supporting member 10 and subsequently forming the light absorbing layer 32. The temporary fixation material precursor layer 30 having the configuration illustrated in FIG. 2(c) can be produced by, for example, alternately forming the light absorbing layer 32, the resin layer 34, and the light absorbing layer 32 on the supporting member 10. Such a temporary fixation material precursor layer 30 may be produced by producing a laminate film for a temporary fixation material having the above-described configuration in advance and laminating the laminate film on the supporting member 10.

The thickness of the temporary fixation material precursor layer 30 (total thickness of the light absorbing layer 32 and the resin layer 34) may be similar to the thickness of the above-mentioned laminate film for a temporary fixation material.

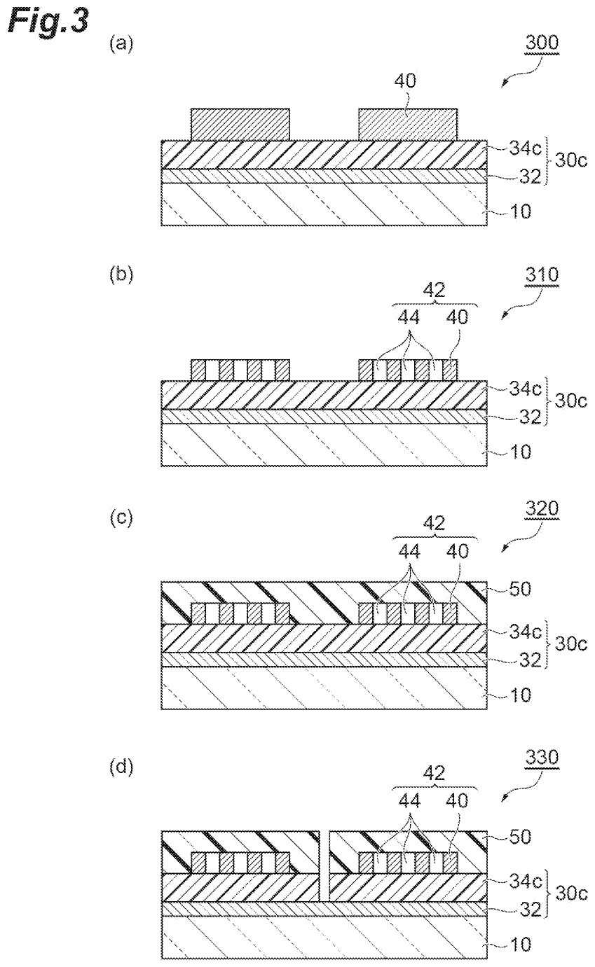

Next, a semiconductor member is disposed on the temporary fixation material precursor layer thus produced, the curable resin component in the temporary fixation material precursor layer 30 (resin layer 34) is cured, a temporary fixation material layer having the light absorbing layer and the resin cured product layer including the cured product of the curable resin component is formed, and thereby a laminate in which the supporting member 10, the temporary fixation material layer 30c, and the semiconductor member 40 are laminated in this order is produced (FIG. 1(a)). FIGS. 3(a), 3(b), 3(c), and 3(d) are schematic cross-sectional views illustrating an embodiment of a laminated body formed using the temporary fixation material precursor layer illustrated in FIG. 2(a).

The semiconductor member 40 may be a semiconductor wafer or a semiconductor chip obtained by cutting a semiconductor wafer into a predetermined size and individualizing the semiconductor into a chip form. In the case of using a semiconductor chip as the semiconductor member 40, usually, a plurality of semiconductor chips is used. The thickness of the semiconductor member 40 may be 1 to 1000 μm, 10 to 500 μm, or 20 to 200 μm, from the viewpoints of suppressing cracking during conveyance, on the occasion of processing steps, and the like, in addition to size reduction and thickness reduction of the semiconductor device. The semiconductor wafer or the semiconductor chip may comprise a rewiring layer, a pattern layer, or an external connection member having an external connection terminal.

The semiconductor member 40 can be laminated by providing a supporting member 10 provided with the temporary fixation material precursor layer 30 thus produced, on a vacuum press machine or a vacuum laminator, disposing the semiconductor member 40 on the temporary fixation material precursor layer 30, and pressure-bonding the assembly with a press.

In the case of using a vacuum press machine, for example, the semiconductor member 40 is pressure-bonded to the temporary fixation material precursor layer 30 at an air pressure of 1 hPa or less, a pressure-bonding pressure of 1 MPa, a pressure-bonding temperature of 120° C. to 200° C., and a retention time of 100 to 300 seconds.

In the case of using a vacuum laminator, for example, the semiconductor member 40 is pressure-bonded to the temporary fixation material precursor layer 30 at an air pressure of 1 hPa or less, a pressure-bonding temperature of 60° C. to 180° C. or 80° to 150° C., a lamination pressure of 0.01 to 0.5 MPa or 0.1 to 0.5 MPa, and a retention time of 1 to 600 seconds or 30 to 300 seconds.

After the semiconductor member 40 is disposed on the supporting member 10, with the temporary fixation material precursor layer 30 interposed therebetween, the curable resin component in the temporary fixation material precursor layer 30 is heat-cured or photocured under predetermined conditions. The conditions for heat-curing may be, for example, 300° C. or lower or 100° C. to 200° C. for 1 to 180 minutes or for 1 to 60 minutes. As such, a cured product of the curable resin component is formed, the semiconductor member 40 is temporarily fixed to the supporting member 10, with a temporary fixation material layer 30c including a cured product of the curable resin component interposed therebetween, and thus a laminated body 300 is obtained. The temporary fixation material layer 30c can be configured to include, as illustrated in FIG. 3(a), a light absorbing layer 32 and a resin cured product layer 34c including a cured product of the curable resin component.

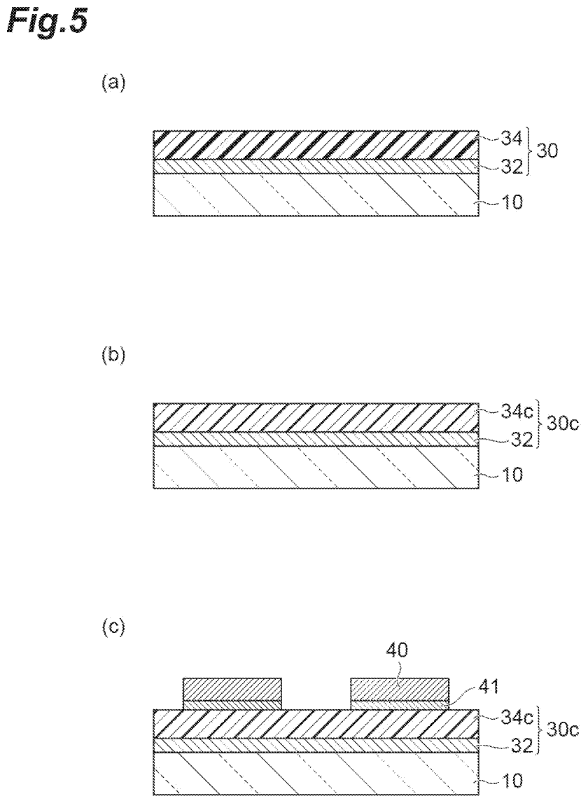

The laminated body can also be produced by, for example, forming a temporary fixation material layer and then disposing a semiconductor member. FIG. 5 is a schematic cross-sectional view for describing another embodiment of the method for manufacturing a laminated body illustrated in FIG. 1(a), and FIGS. 5(a), 5(b), and 5(c) are schematic cross-sectional views illustrating the respective steps. The respective steps of FIG. 5 use the temporary fixation material precursor layer illustrated in FIG. 2(a). A laminated body can be produced by forming a temporary fixation material precursor layer 30 including a curable resin component on a supporting member 10 (FIG. 5(a)), curing the curable resin component in the temporary fixation material precursor layer 30 (resin layer 34), forming a temporary fixation material layer 30c including a cured product of the curable resin component (FIG. 5(b)), and disposing a semiconductor member 40 on the temporary fixation material layer 30c thus formed (FIG. 5(c)). In such a manufacturing method, since a wiring layer 41 such as a rewiring layer or a pattern layer can be provided on the temporary fixation material layer 20c before the semiconductor member 40 is disposed, a semiconductor member 40 having the wiring layer 41 can be formed by disposing the semiconductor member 40 on the wiring layer 41.

The semiconductor member 40 (semiconductor member 40 temporarily fixed onto the supporting member 10) in the laminated body 100 may be further processed. By processing the semiconductor member 40 in the laminated body 300 illustrated in FIG. 3(a), laminated bodies 310 (FIG. 3(b)), 320 (FIG. 3(c)), 330 (FIG. 3(d)), and the like are obtained. Processing of the semiconductor member is not particularly limited; however, examples thereof include thinning of the semiconductor member, production of a penetration electrode, formation of a penetration electrode, formation of a wiring layer such as a rewiring layer or a pattern layer, an etching treatment, a plating reflow treatment, and a sputtering treatment.

Thinning of the semiconductor member can be carried out by grinding a surface of the semiconductor member 40, the surface being on the opposite side of the surface that is in contact with the temporary fixation material layer 30c, using a grinder or the like. The thickness of the thinned semiconductor member may be, for example, 100 μm or less.

The grinding conditions can be arbitrarily set according to the desired thickness of the semiconductor member, the grinding state, and the like.

The production of a penetration electrode can be carried out by performing processing such as dry ion etching or a Bosch process on a surface of the thinned semiconductor member 40, the surface being on the opposite side of the surface that is in contact with the temporary fixation material layer 30c, forming through-holes, and then subjecting the semiconductor member 40 to a treatment such as copper plating.

In this way, the semiconductor member 40 is subjected to processing, for example, the semiconductor member 40 is thinned, and a laminated body 310 having a penetration electrode 44 provided therein (FIG. 3(b)) can be obtained.

The laminated body 310 illustrated in FIG. 3(b) may be covered with a sealing layer 50 as illustrated in FIG. 3(c). There are no particular limitations on the material for the sealing layer 50; however, from the viewpoints of heat resistance as well as reliability, and the like, the material may be a thermosetting resin composition. Examples of the thermosetting resin to be used for the sealing layer 50 include epoxy resins such as a cresol novolac epoxy resin, a phenol novolac epoxy resin, a biphenyl diepoxy resin, and a naphthol novolac epoxy resin. In the composition for forming the sealing layer 50, additives such as a filler and/or a flame-retardant substance such as a bromine compound may be added thereto.

The supply form of the sealing layer 50 is not particularly limited; however, the supply form may be a solid material, a liquid material, a fine granular material, a film material, or the like.

For the sealing of the processed semiconductor member 42 by means of a sealing layer 50 formed from a sealing film, for example, a compression sealing molding machine or a vacuum lamination apparatus is used. A sealing layer 50 can be formed using the above-described apparatus, for example, by covering the processed semiconductor member 42 with a sealing film that has been heat-melted under the conditions of 40° C. to 180° C. (or 60° C. to 150° C.), 0.1 to 10 MPa (or 0.5 to 8 MPa), and 0.5 to 10 minutes. The sealing film may be prepared in a state of being laminated on a release liner such as a polyethylene terephthalate (PET) film. In this case, the sealing layer 50 can be formed by disposing the sealing film on the processed semiconductor member 42, embedding the processed semiconductor member 42 therein, and then detaching the release liner. In this way, the laminated body 320 illustrated in FIG. 3(c) can be obtained.

The thickness of the sealing film is adjusted such that the sealing layer 50 is thicker than or equal to the thickness of the processed semiconductor member 42. The thickness of the sealing film may be 50 to 2000 μm, 70 to 1500 μm, or 100 to 1000 μm.

The processed semiconductor member 42 having the sealing layer 50 may be individualized by dicing, as illustrated in FIG. 3(d). In this way, the laminated body 330 illustrated in FIG. 3(d) can be obtained. Meanwhile, individualization by dicing may be carried out after the separation step for the semiconductor member that will be described below.

<Separation Step for Semiconductor Member>

As illustrated in FIG. 1(b), in the separation step for the semiconductor member, the temporary fixation material layer 30c in the laminated body 100 is irradiated with light in direction A, and then the semiconductor member 40 is separated from the supporting member 10.

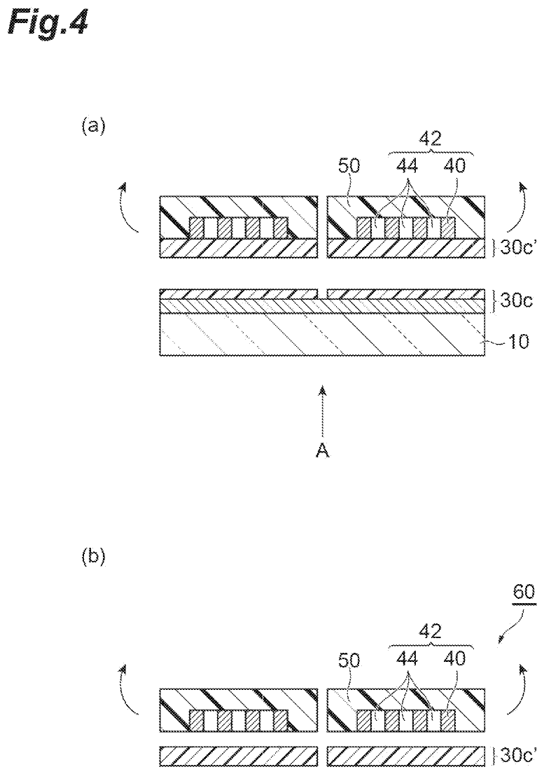

FIG. 4 is a schematic cross-sectional view for describing an embodiment of the semiconductor device manufacturing method of the present invention using the laminated body illustrated in FIG. 3(d), and FIGS. 4(a) and 4(b) are schematic cross-sectional views illustrating the respective steps.

When the temporary fixation material layer 30c is irradiated with light, the light absorbing layer 32 absorbs light and instantaneously generates heat, and at the interface or in the bulk, melting of the resin cured product layer 34c, stress between the supporting member 10 and the semiconductor member 40 (processed semiconductor member 42), scattering of the light absorbing layer 32, and the like can occur. As a result of the occurrence of such phenomena, the processed semiconductor member 42 that is temporarily fixed can be easily separated (detached) from the supporting member 10. Meanwhile, in the separation step, along with irradiation with light, stress may be slightly applied to the processed semiconductor member 42 in a direction parallel to the principal plane of the supporting member 10.

The light for the separation step may be incoherent light. Incoherent light is electromagnetic waves having properties that interference fringes are not generated, coherence is low, and directivity is low, and as the optical path length is longer, the incoherent light tends to be attenuated. Incoherent light is a light that is not coherent light. While laser light is generally coherent light, light such as sunlight or fluorescent lamp light is incoherent light. Incoherent light can be said to be any light excluding laser light. Since the irradiation area of the incoherent light is overwhelmingly larger than coherent light (that is, laser light), it is possible to reduce the number of times of irradiation (for example, one time).

The light for the separation step may be any light including at least infrared light. The light source for the light in the separation step is not particularly limited; however, the light source may be a xenon lamp. A xenon lamp is a lamp that utilizes light emission caused by application and discharge in an arc tube having xenon gas enclosed therein. Since a xenon lamp is discharged while ionization and excitation are repeated, the xenon lamp stably has continuous wavelengths from the ultraviolet light region to the infrared light region. In a xenon lamp, since the time required for starting is short compared to lamps such as a metal halide lamp, the time related to the process can be shortened to a large extent. Furthermore, regarding light emission, since it is necessary to apply a high voltage, high heat is instantaneously generated; however, the cooling time is short, and a continuous operation is enabled. Furthermore, since the irradiation area of a xenon lamp is overwhelmingly large compared to laser light, it is possible to reduce the number of times of irradiation (for example, one time).

Regarding the conditions for irradiation by a xenon lamp, the voltage to be applied, the pulse width, the irradiation time, the irradiation distance (distance between the light source and the temporary fixation material layer), the irradiation energy, and the like can be arbitrarily set up. Regarding the conditions for irradiation by a xenon lamp, conditions in which separation is enabled by irradiation for one time may be set up, or conditions in which separation is enabled by irradiation for two or more times may be set up; however, from the viewpoint of reducing damage to the processed semiconductor member 42, regarding the conditions for irradiation by a xenon lamp, conditions in which separation is enabled by irradiation for one time may be set up.

The separation step may be a step of irradiating the temporary fixation material layer 30c with light through the supporting member 10 (direction A in FIG. 4(a)). That is, the irradiation of the temporary fixation material layer 30c with light may be irradiation through the supporting member 10 side. By irradiating the temporary fixation material layer 30c with light through the supporting member 10, it is possible to irradiate the entirety of the temporary fixation material layer 30c.

When the semiconductor member 40 or the processed semiconductor member 42 is separated from the supporting member 10, in a case in which residue 30c′ (FIGS. 4(a) and 4(b)) of the temporary fixation material layer is attached to the semiconductor member 40 or the processed semiconductor member 42, these can be washed with a solvent. The solvent is not particularly limited; however, examples thereof include ethanol, methanol, toluene, xylene, acetone, methyl ethyl ketone, methyl isobutyl ketone, and hexane. These may be used singly or in combination of two or more kinds thereof. Furthermore, the semiconductor member 40 or the processed semiconductor member 42 may be immersed in these solvents or may be subjected to ultrasonic cleaning. Furthermore, the member may also be heated in the range of 100° C. or lower.

By separating the semiconductor member from the supporting member as such, a semiconductor element 60 including the semiconductor member 40 or the processed semiconductor member 42 is obtained (FIG. 4(b)). A semiconductor device can be manufactured by connecting the semiconductor element 60 thus obtained to another semiconductor element or a substrate for mounting semiconductor elements.

[Laminate Film for Temporary Fixation Material]

The above-mentioned laminate film having a light absorbing layer that generates heat upon absorbing light and a resin layer including a curable resin component, in which the curable resin component includes a hydrocarbon resin and the storage modulus at 25° C. for a cured product of the curable resin component is 5 to 100 MPa, can be suitably used as a temporary fixation material for temporarily fixing a semiconductor member to a supporting member.

### EXAMPLES

Hereinafter, the present invention will be more specifically described by way of Examples. However, the present invention is not intended to be limited to these Examples.

### Example 1

<Preparation of Curable Resin Component>

A mixture was obtained by mixing 70 parts by mass of a maleic anhydride-modified styrene-ethylene-butylene-styrene block copolymer (trade name: FG1924, Kraton Polymers Japan, Ltd., styrene content: 13% by mass) as a hydrocarbon resin, 30 parts by mass of a dicyclopentadiene type epoxy resin (trade name: HP7200, DIC Corporation) as an epoxy resin, and 1 part by mass of 1-benzyl-2-methylimidazole (trade name: CUREZOL 1B2MZ, SHIKOKU CHEMICALS CORPORATION) as a curing accelerator. Meanwhile, regarding the hydrocarbon resin, a resin diluted with toluene to a solid content of 25% by mass was used. These were stirred for 10 minutes at a rate of 2200 rotations/min using an automatic stirring apparatus, and a varnish of a curable resin component diluted with toluene as a solvent was prepared.

<Production of Curable Resin Component Film>

The varnish of the curable resin component thus obtained was applied to a thickness of 20 μm on a release-treated surface of a polyethylene terephthalate (PET) film (PUREX A31, DuPont Teijin Films, Ltd., thickness: 38 μm) using a precision coating machine, the varnish was heated for 10 minutes at 90° C. to dry and remove the solvent, and a curable resin component film (resin layer) having a thickness of 20 μm was produced. Furthermore, the varnish was applied to a thickness of 200 μm and heated for 15 to 20 minutes at 90° C. to dry and remove the solvent, and a curable resin component film (resin layer) having a thickness of 200 μin was produced.

<Measurement of Storage Modulus>

The curable resin component film having a thickness of 200 μm thus obtained was cut out into a predetermined size [20 mm in length (distance between chucks)×5 0 mm in width], the cut film was thermally cured in a clean oven (manufactured by ESPEC CORP.) under the conditions of 180° C. and 2 hours, and a measurement sample, which was a cured product of the curable resin component film (resin cured product layer), was obtained. The storage moduli at 25° C. and 250° C. for the cured product of the curable resin component film (resin cured product layer) were measured under the following conditions. The results are presented in Table 2.

Apparatus name: Dynamic viscoelasticity measuring apparatus (manufactured by TA Instruments, Inc., RSA-G2)

Measurement temperature region: −70° C. to 300° C.

Rate of temperature increase: 5° C./min

Frequency: 1 Hz

Measurement mode: Tensile mode

<Production of Light Absorbing Layer>

A light absorbing layer in which a first conductor layer was formed of titanium, and a second conductor layer was formed of copper, was produced by sputtering on a slide glass (size: 40 mm×40 mm, thickness: 0.8 μm), which was a supporting member, and a supporting member including a light absorbing layer was obtained. The light absorbing layer was produced by performing a preliminary treatment by back sputtering (Ar flow rate: 1.2×10⁻² Pa·m³/s (70 sccm), RF power: 300 W, time: 300 seconds), subsequently performing RF sputtering under the treatment conditions shown in Table 1, and adjusting the thicknesses of the titanium layer/copper layer to 50 nm/200 nm.

TABLE 1

| | | Electrical |
|---|---|---|
| Sputtering treatment | Ar flow rate | power |
| Treatment 1 (production | 1.2 × 10⁻² Pa · m³/s (70 sccm) | 2000 W |
| of titanium layer) | | |
| Treatment 2 (production | 1.2 × 10⁻² Pa · m³/s (70 sccm) | 2000 W |
| of copper layer) | | |

<Production of Laminate Film for Temporary Fixation Material>

The curable resin component film (resin layer) having a thickness of 20 μm was cut out to a size of 40 mm×40 mm The cut curable resin component film (resin layer) was disposed on the light absorbing layer of the supporting member having the light absorbing layer thus obtained, the assembly was subjected to vacuum lamination, and a laminate film for a temporary fixation material of Example 1 provided on a supporting member was produced.

<Production of Laminated Body>

On the curable resin component film (resin layer) of the laminate film for a temporary fixation material thus obtained, a semiconductor chip (size: 10 mm×10 mm, thickness: 150 μm) as a semiconductor member was mounted, the assembly was thermally cured under the conditions of one hour at 180° C., and thereby a laminated body of Example 1 was obtained.

### Example 2

The production was carried out in the same manner as in Example 1, except that the hydrocarbon resin of Example 1 was changed to 35 parts by mass of a maleic anhydride-modified styrene-ethylene-butylene-styrene block copolymer (trade name: FG1924, Kraton Polymers Japan, Ltd., styrene content: 13% by mass) and 35 parts by mass of a maleic anhydride-modified styrene-ethylene-butylene-styrene block copolymer (trade name: FG1901, Kraton Polymers Japan, Ltd., styrene content: 30% by mass), the storage moduli at 25° C. and 250° C. for a cured product of the curable resin component film (resin cured product layer) were measured, and a laminate film for a temporary fixation material and a laminated body of Example 2 were produced. The results for the storage moduli at 25° C. and 250° C. are presented in Table 2.

### Example 3

The production was carried out in the same manner as in Example 1, except that a silica filler (trade name: R972, NIPPON AEROSIL CO., LTD.) was added at a proportion of 10% by mass based on the total amount of the hydrocarbon resin and the epoxy resin, the storage moduli at 25° C. and 250° C. for a cured product of the curable resin component film (resin cured product layer) were measured, and a laminate film for a temporary fixation material and a laminated body of Example 3 were produced. The results for the storage moduli at 25° C. and 250° C. are presented in Table 2.

### Comparative Example 1

The production was carried out in the same manner as in Example 1, except that the epoxy resin used in Example 1 was changed to 30 parts by mass of 3′,4′-epoxycyclohexylmethyl-3,4-epoxycyclohexane carboxylate (trade name: CELLOXIDE 2021P, Daicel Corporation), the storage moduli at 25° C. and 250° C. for a cured product of the curable resin component film (resin cured product layer) were measured, and a laminate film for a temporary fixation material and a laminated body of Comparative Example 1 were produced. The results for the storage moduli at 25° C. and 250° C. are presented in Table 2.

### Comparative Example 2

The production was carried out in the same manner as in Example 1, except that the mass ratio between the hydrocarbon resin and the epoxy resin was changed from 70:30 to 80:20, the storage moduli at 25° C. and 250° C. for a cured product of the curable resin component film (resin cured product layer) were measured, and a laminate film for a temporary fixation material and a laminated body of Comparative Example 2 were produced. The results for the storage moduli at 25° C. and 250° C. are presented in Table 2.

### Comparative Example 3

The production was carried out in the same manner as in Example 1, except that the hydrocarbon resin of Example 1 was changed to 70 parts by mass of a maleic anhydride-modified styrene-ethylene-butylene-styrene block copolymer (trade name: FG1901, Kraton Polymers Japan, Ltd., styrene content: 30% by mass), the storage moduli at 25° C. and 250° C. for a cured product of the curable resin component film (resin cured product layer) were measured, and a laminate film for a temporary fixation material and a laminated body of Comparative Example 3 were produced. The results for the storage moduli at 25° C. and 250° C. are presented in Table 2.

<Detachability Test>

Two laminated bodies for each Example were prepared. Each of the laminated bodies was irradiated using a xenon lamp under two kinds of irradiation conditions, namely, irradiation conditions A including an applied voltage of 3800 V, a pulse width of 200 μs, an irradiation distance of 50 mm, a number of times of irradiation of one time, and an irradiation time of 200 μs, and irradiation conditions B including an applied voltage of 2700 V, a pulse width of 1000 μs, an irradiation distance of 50 mm, a number of times of irradiation of one time, and an irradiation time of 1000 μs, and detachability from the supporting member was evaluated. Regarding the xenon lamp, S2300 (wavelength range: 270 nm to near-infrared region, irradiation energy per unit area: 7 J/cm² (expected value, irradiation conditions A), 13 J/cm² (expected value, irradiation conditions B)) manufactured by XENON Corporation was used, and irradiation using the xenon lamp was carried out through the supporting member (slide glass) side of the laminated body. The irradiation distance is the distance between the light source and the stage where the slide glass was installed. Regarding the evaluation of the detachability test, a case in which the semiconductor chip was spontaneously detached from the slide glass after being irradiated with the xenon lamp, was rated as “A”; a case in which when tweezers were inserted between the semiconductor chip and the slide glass under either of the irradiation conditions, the semiconductor chip was separated without being damaged, was rated as “B”; and a case in which the semiconductor chip was not separated under either of the irradiation conditions, was rated as “C”. The results are presented in Table 2.

TABLE 2

| | Storage modulus | Storage modulus | Detachability test | |
|---|---|---|---|---|
| | after curing | after curing | Irradiation | Irradiation |
| | (MPa, 25° C.) | (MPa, 250° C.) | conditions A | conditions B |
| Comp. Example 1 | 0.4 | 0.16 | C | C |
| Comp. Example 2 | 4.2 | 0.66 | C | C |
| Example 1 | 6.3 | 0.93 | A | A |
| Example 2 | 29.8 | 1.31 | A | A |
| Example 3 | 62.8 | 1.73 | A | A |
| Comp. Example 3 | 125.0 | 2.10 | B | B |

As shown in Table 2, the laminated bodies of Examples 1 to 3, in which the storage moduli at 25° C. for the cured products of the curable resin components were 5 to 100 MPa, had excellent detachability from the supporting member, as compared to the laminated bodies of Comparative Examples 1 to 3, in which the storage moduli at 25° C. for the cured products of the curable resin components did not satisfy the above-described requirements. From the results described above, it was verified that in the semiconductor device manufacturing method of the present invention, the temporarily fixed semiconductor member can be easily separated from the supporting member.

### REFERENCE SIGNS LIST

10: supporting member, 30: temporary fixation material precursor layer, 30c: temporary fixation material layer, 30c′: residue of temporary fixation material layer, 32: light absorbing layer, 34: resin layer, 34c: resin cured product layer, 40: semiconductor member, 41: wiring layer, 42: processed semiconductor member, 44: penetration electrode, 50: sealing layer, 60: semiconductor element, 100, 300, 310, 320, 330: laminated body.

1. A semiconductor device manufacturing method, comprising:
preparing a laminated body by sequentially laminating supporting member, a temporary fixation material layer that generates heat upon absorbing light, and a semiconductor member; and
irradiating the temporary fixation material layer in the laminated body with light to separate the semiconductor member from the supporting member,
wherein the temporary fixation material layer includes:
a light absorbing layer that generates heat by absorbing the light; and
a resin cured product layer including a cured product of a curable resin component, wherein the curable resin component comprises a hydrocarbon resin, and wherein a storage modulus at 25° C. for the cured product of the curable resin component is 5 to 100 MPa.

2. The semiconductor device manufacturing method according to claim 1, wherein a light source of the light used to irradiate the temporary fixation material layer includes a xenon lamp.

3. The semiconductor device manufacturing method according to claim 12, wherein the light used to irradiate the temporary fixation material layer includes at least infrared light.

4. The semiconductor device manufacturing method according to claim 1, wherein the temporary fixation material layer is irradiated with the light through the supporting member to separate the semiconductor member from the supporting member.

5. The semiconductor device manufacturing method according to claim 1, wherein the curable resin component further comprises a thermosetting resin.

6. A laminate film for temporarily fixing a semiconductor member to a supporting member, the laminate film comprising:
a light absorbing layer that generates heat by absorbing light and
a resin layer including a curable resin component, wherein the curable resin component comprises a hydrocarbon resin, and wherein a storage modulus at 25° C. for a cured product of the curable resin component is 5 to 100 MPa.

7. The laminate film according to claim 6, wherein a thickness of the resin layer is 50 μm or less.

8. The laminate film according to claim 6, wherein the curable resin component further comprises a thermosetting resin.

9. The laminate film according to claim 6, wherein the light absorbing layer comprises a first conductor layer and a second conductor layer located adjacent to and in contact with the first conductor layer.

10. The laminate film according to claim 9, wherein the first conductor layer comprises titanium, and wherein the second conductor layer comprises at least one conductive material selected from the group consisting of copper, aluminum, silver, gold, and platinum

11. A laminated body comprising the laminate film according to claim 6, wherein the laminate film is layered between the supporting member and the semiconductor member to form the laminated body.

12. The laminated body according to claim 11, wherein the light absorbing layer is configured to absorb the light through the supporting member to separate the semiconductor member from the laminated body.

13. The laminated body according to claim 11, wherein the light absorbing layer is located between the resin cured product layer and the supporting member.

14. The laminated body according to claim 11, wherein the light absorbing layer comprises:
a first conductor layer located adjacent to and in contact with the supporting member; and
a second conductor layer located between the first conductor layer and the semiconductor member.

15. The laminated body according to claim 14, wherein the second conductor layer is located adjacent to and in contact with the first conductor layer.

16. The laminated body according to claim 14, wherein the first conductor layer comprises titanium.

17. The laminated body according to claim 16, wherein the second conductor layer comprises at least one conductive material selected from the group consisting of copper, aluminum, silver, gold, and platinum.

18. The semiconductor device manufacturing method according to claim 1, wherein the light absorbing layer is located between the resin cured product layer and the supporting member.

19. The semiconductor device manufacturing method according to claim 18, wherein the light absorbing layer comprises:
a first conductor layer provided on the supporting member; and
a second conductor layer provided on the first conductor layer, the first conductor layer located between the second conductor layer and the supporting member.

20. The semiconductor device manufacturing method according to claim 19, wherein the first conductor layer comprises titanium and the second conductor layer comprises at least one selected from the group consisting of copper, aluminum, silver, gold, and platinum.
